(19) United States
(12) Patent Application Publication
(10) Pub. No.: US 2007/0278945 A1
(43) Pub. Date: Dec. 6, 2007

(54) Organic electroluminescence device and display unit

(76) Inventors: Yuko Abe, Tokyo (JP); Eiichi Kitazume, Tokyo (JP); Hajime Yokoi, Tokyo (JP); Ryo Shoda, Tokyo (JP)

Correspondence Address: SQUIRE, SANDERS & DEMPSEY L.L.P., 1 MARITIME PLAZA, SUITE 300, SAN FRANCISCO, CA, 94111, US

(21) Appl. No.: 11/698,604

(22) Filed: Jan. 25, 2007

(30) Foreign Application Priority Data
Jun. 1, 2006 (JP) 2006-152951

(51) Int. Cl. H01L 51/52; H01L 51/54

(52) U.S. Cl. 313/506; 313/504; 428/690; 428/917; 257/101; 257/E51.048

(57) ABSTRACT

The present invention provides an organic EL device, which is long-life and has high performance, by optimizing the hole transport layer. An organic electroluminescence device including at least a first electrode 102, an organic electroluminescence medium layer 103 having a hole transport layer 103a and an organic luminescent layer 103b, and a second electrode 104 in this order, wherein the hole transport layer 103a includes associates of a donating molecule and an accepting molecule, and the hole transport layer 103a has different component ratios of the donating molecule and the accepting molecule between the side of the first electrode 102 and the side of the organic luminescent layer 103b.

### CROSS REFERENCE

This application claims priority to Japanese application number 2006-152951, filed on Jun. 1, 2006, which is incorporated by reference.

### BACKGROUND OF THE INVENTION

1. Field of the Invention

The present invention relates to an organic electroluminescence device (an organic light emitting diode), and in particular, relates to an organic electroluminescence device including an organic electroluminescence medium layer having a laminated structure of polymer films.

2. Description of the Related Art

In organic electroluminescence (organic EL) devices, voltage is applied to electrically conductive organic electroluminescence medium layer, and thus injected electrons and holes are allowed to recombine, whereby an organic luminescent material constructing the organic electroluminescence medium layer is allowed to emit light upon this recombination. For extracting the light outside concurrently with applying the voltage to the organic electroluminescence medium layer, construction including a first electrode and a second electrode placed on both sides of the organic electroluminescence medium layer is provided. This device is constructed by sequentially laminating the first electrode, the organic electroluminescence medium layer and the second electrode on a board. In general, the first electrode formed on the board is used as an anode, while the second electrode formed on the organic electroluminescence medium layer is used as a cathode.

Exemplary organic electroluminescence medium layer may be one including copper phthalocyanine used as a hole injection layer, N,N′-di(1-naphthyl)-N,N′-diphenyl-1,1′-biphenyl-4,4′-diamine used as a hole transport layer, and tris(8-quinolinol) aluminum used as a luminescent layer, respectively.

Furthermore, in an attempt to increase luminous efficiency, construction as an organic EL device is often made by providing the hole transport layer and the hole injection layer between the anode and the organic luminescent layer, or the electron transport layer and the electron injection layer between the organic luminescent layer and the cathode, which may be selected ad libitum. The organic luminescent layer, the hole transport layer, the hole injection layer, the electron transport layer, and the electron injection layer are referred to as the organic electroluminescence medium layer in combination.

Any of the substances which constitute the organic electroluminescence medium layer to perform the function (electroluminescence medium material) is a low molecular compound, each layer having a thickness of approximately 1 to 100 nm, and laminated by a vacuum evaporation method such as resistance heating. Manufacturing the organic thin film EL device with a low molecular materials needs a vacuum evaporation equipments connected to multiple vapor deposition vessels. This may lead to problems of low productivity accompanied by high manufacturing cost.

To the contrary, there are polymer organic EL devices in which a polymer material is used as the organic electroluminescence medium layer. In the light emitting layer, a low molecular light-emitting material dissolved in a polymer such as polystyrene, polymethyl methacrylate or polyvinyl carbazole, as well as a polymer light emitter such as a polyphenylenevinylene derivative (PPV), a polyalkylfluorene derivative (PAF) or the like may be used. These polymer materials can be subjected to film formation by a wet method such as a coating method or a printing method through dissolving or dispersing in a solvent. Therefore, it is advantageous in that film production is enabled under an ambient air pressure with low equipment cost as compared with the organic EL device in which the low molecular material is used.

In the polymer organic EL device, a hole injection layer is generally provided for the purpose of lowering the voltage to be applied. In typical examples, film formation is carried out using an ink of associates,of a donating molecule and an accepting molecule which were dispersed in water. However, when resulting hole injection layer is inadequate, hole injection efficiency or hole transporting ability may be exacerbated, thereby leading to impaired carrier balance between the electrons and the holes, whereby causing the problems of lowering the lifetime and deteriorated luminous efficiency. Also, impurities included in this hole injection layer may be contaminated in adjacent organic luminescent layer, whereby a problem of lowering the lifetime may be raised.

For solving these problems, an invention was made which can prolong the lifetime of the organic EL device by using a solution or dispersion of a polymeric organic electric conductor having a diameter of 1 μm or less as a hole transport layer. However, although occurrence of a short between the electrodes is extremely reduced, thereby solving the problem of instability with time according to the invention described in Patent Document 1, lifetime of the light emitter is not referred to.

The invention was made in view of the foregoing problems, and an object of the present invention is to provide an organic EL device, which is long-life and has high performance, by optimizing the hole transport layer.

Patent Document 1: JP-A-2000-91081

### SUMMARY OF THE INVENTION

The present invention provides an organic EL device, which is long-life and has high performance, by optimizing the hole transport layer. An aspect of the invention is an organic electroluminescence device including at least a first electrode 102, an organic electroluminescence medium layer 103 having a hole transport layer 103a and an organic luminescent layer 103b, and a second electrode 104 in this order, wherein the hole transport layer 103a includes associates of a donating molecule and an accepting molecule, and the hole transport layer 103a has different component ratios of the donating molecule and the accepting molecule between the side of the first electrode 102 and the side of the organic luminescent layer 103b.

### BRIEF DESCRIPTION OF THE DRAWINGS

FIG. 1 shows a cross-sectional view for illustrating a structure of the organic EL device of the present invention.

FIG. 2 shows a schematic view illustrating a printing machine for carrying out letterpress printing.

FIG. 3 shows a cross-sectional view for illustrating a structure of the organic EL device produced in Example of the invention.

### DESCRIPTION OF REFERENCE NUMERALS AND SIGNS

101, 301; translucent board, 102, 302; transparent conductive layer, 103, 303; organic electroluminescence medium layer, 103a, 303a; hole transport layer, 103b, 303b; organic luminescent layer (organic light emitting layer), 104, 304; counter electrode, 105, 305; insulating partition, 201; ink tank, 202; ink chamber, 203; anilox roll, 204; resin letterpress, 205; plate cylinder, 206; coating liquid for printing, 207; stage, 208; board to be printed.

### DESCRIPTION OF THE PREFERRED EMBODIMENTS

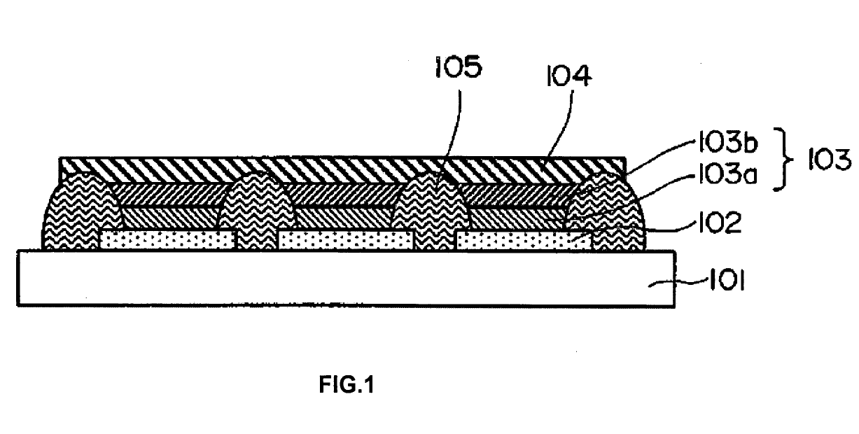

Hereinafter, one example of the organic EL device according to the present invention will be explained with reference to FIG. 1.

In FIG. 1, a translucent board 101 in the invention is not particularly limited as long as it is a substrate having translucency and a certain level of strength, and specifically, a glass board, or a plastic film or sheet can be used. When a thin glass board having a thickness of 0.2 to 1 mm is used, a thin organic EL device having extremely high barrier properties can be produced.

A transparent conductive layer 102 as the first electrode is not particularly limited as long as it is formed with an electrically conductive material enabling formation of a transparent or translucent electrode. Specifically, a complex oxide of indium and tin (hereinafter, referred to as ITO) can be preferably used. The film can be formed on the translucent board 101 with a vapor deposition or sputtering method. Also, it can be formed by coating a precursor such as indium octylate or acetone indium on the substrate, followed by an application thermal decomposition method in which oxide is formed by thermal decomposition. Alternatively, a metal such as aluminum, gold or silver may be used after vacuum evaporation to give a translucent state. Alternatively, an organic semiconductor such as polyaniline can be also used.

The transparent conductive layer 102 as described above may be subjected to patterning by etching, or to surface activation by a UV treatment, a plasma treatment or the like as needed.

When the organic EL device is manufactured to obtain a display that enables matrix display, the transparent conductive layer 102 is formed in stripes, and by forming the second electrode (counter electrode), which is formed across an organic electroluminescence medium layer, in stripes so as to be perpendicular to the transparent electrode, passive matrix display can be obtained in which each intersection emits light. Also, an active matrix display can be obtained by forming thin film transistors so that they correspond to each picture element on the translucent board 101, and arranging the counter electrode that corresponds to each picture element so as to each conduct thereto.

When the transparent conductive layer 102 is formed by etching to give a patterned shape, concern about possible occurrence of a short between the first electrode and the counter electrode may be raised in the case in which the edge of the transparent conductive layer cannot be covered by the organic electroluminescence medium layer laminated thereon. Therefore, the end part of the first electrode is preferably covered by a resin having an insulating property. In order to cover the end part of the first electrode, for example, photosensitivity is imparted to a composition of a resin such as polyimide, acryl or polyurethane, which is coated, followed by mask exposure and development.

Additionally, when the height of the resin having the insulating property (designated as insulating partition 105) that covers the end part of the first electrode is higher than a certain value, for example, 0.5 μm or higher and 1.5 μm or lower, it plays a role in preventing the picture elements from color mixing when the organic electroluminescence medium layers formed according to adjacent first electrode patterns emit the light to develop different colors.

The organic electroluminescence medium layer 103 of the organic EL device according to the invention is not limited to the two-layer structure of the hole transport layer 103a and the organic luminescent layer 103b (FIG. 1), but the structure further provided with an electron transport layer, an electron injection layer or an insulating layer can also exhibit the effect of the invention. Each layer may have an arbitrary thickness, but is preferably 10 nm to 200 nm, and it is preferred that the organic electroluminescence medium layer has a total film thickness of 50 nm to 500 nm.

For the hole transport layer 103a, a dispersion of associates of a donating molecule and an accepting molecule dispersed in water may be used. It is preferred that the donating molecule be polythiophene or a derivative thereof, and the accepting molecule be polystyrenesulfonic acid or a derivative thereof. Specifically, preferable examples of the donating molecule include electrically conductive polymers such as polythiophene, polyaniline and polypyrrole. More preferably, the donating molecule may be poly(3,4-ethylenedioxythiophene) which less absorbs light in the visible light region. Examples of preferably used accepting molecule include acidic polymers such as polyacrylic acid and polystyrenesulfonic acid.

Water in which these donating molecules and accepting molecules are dispersed may be ion exchanged water, or pure water obtained by distillation. In addition, an alcoholic solvent such as methanol, ethanol, propanol or butanol may be also included. By adding the alcoholic solvent, a heat treatment at a low temperature is permitted, and thus content of water can be diminished. Moreover, the addition of the solvent is preferred because decline in the surface tension improves wettability toward the first electrode. However, when the water content is too low, dispersibility of the associates of the donating molecule and the accepting molecule may be concerned, therefore, the water content is preferably 60% or greater in the entire solvent.

The component ratio of the donating molecule and the accepting molecule that constitute the hole transport layer may be any arbitrary value depending on the used material. Because the electric conductivity is improved when the donating molecule is included in a larger amount, the electric current flow is apt to be facilitated, and thus higher luminance can be obtained. However, when the amount of the donating molecule is too much, excessive hole injection may be caused, thereby leading to decrease in luminous efficiency of the entire device. To the contrary, when the accepting molecule is included in a larger amount, resistance of the hole transport layer is raised to result in decrease in probability of the short, however, the driving voltage shifts toward the high voltage side. For example, when poly(3,4-ethylenedioxythiophene) is used as the donating molecule, and polystyrenesulfonic acid is used as the accepting molecule, the ratio of poly(3,4-ethylenedioxythiophene)/polystyrenesulfonic acid employed preferably falls within the range of ⅙ to 1/20.

Because the accepting molecule has surface activity, improvement of the wettability can be intended by increasing viscosity of the dispersion to decline the surface tension. Therefore, to include the accepting molecule in a larger amount is preferred because more uniform film can be formed without void or uneven film thickness when the film formation is carried out by a coating method or a printing method to the first electrode.

In contrast, the accepting molecule is acidic and it is likely to contain free sulfate ion in the case of polystyrenesulfonic acid, therefore, there is concern about causing damage to the adjacent layer. In particular, when lamination of the organic luminescent layer subsequent to the hole transport layer is carried out, it is more preferred that the donating molecules are included in a larger amount on the organic luminescent layer side because it may be responsible for deterioration of the organic luminescent material itself, or quenching.

For forming the hole transport layer, using a hole transport material having different component ratios of the donating molecule and the accepting molecule, the hole transport layer having different component ratios of the donating molecule and the accepting molecule between the first electrode side and the organic luminescent layer side can be readily obtained by using a laminated body produced by laminating two or more hole transport layers.

Dispersion of these hole transport materials can be subjected to the formation by a wet method such as e.g., a spin coating method, a slit coating method, a bar coating method or a roll coating method. Also, patterning may be carried out if necessary using an intaglio printing method, a letterpress printing method, a lithographic printing method, a screen printing method or the like.

The light emitting material for use in the organic luminescent layer 103b may be any one as long as it is a material which is generally used as an organic luminescent material, and the film formation can be carried out by vacuum evaporation using a known low molecular material such as a coumarin-based, perylene-based, pyran-based, anthrone-based, porphyrene-based, quinacridone-based, N,N′-dialkyl-substituted quinacridone-based, naphthalimido-based or N,N′-diaryl-substituted pyrrolopyrrole-based low molecular material.

Alternatively, a light-emitting dye stuff (material) such as a coumarin-based, perylene-based, pyran-based, anthrone-based, PORUFIREN-based, quinacridone-based, N,N′-dialkyl-substituted quinacridone-based, naphthalimido-based, or N,N′-diaryl-substituted pyrrolopyrrole-based dissolved in a polymer such as polystyrene, polymethyl methacrylate or polyvinyl carbazole, as well as a PPV-based or PAF-based polymer light emitter or the like can be used. These polymer organic luminescent layer can be formed by a printing method using an organic light-emitting coating liquid prepared by dissolving or dispersing in a solvent such as toluene, xylene, acetone, anisole, methyl anisole, dimethyl anisole, ethyl benzoate, methyl benzoate, mesitylene, tetralin, amyl benzene, methyl ethyl ketone, methyl isobutyl ketone, cyclohexanone, methanol, ethanol, isopropyl alcohol, ethyl acetate, butyl acetate or water alone or as a mixed solvent. In particular, an aromatic solvent such as toluene, xylene, anisole, methyl anisole, dimethyl anisole, ethyl benzoate, methyl benzoate, mesitylene, tetralin or amyl benzene is more preferred because it is favorable in solubility of the polymer luminescent material, and can be easily handled.

The hole blocking material and the electron transport material used in the hole blocking layer and the electron transport layer may be any one as long as it is a generally used electron transport material, and the film formation can be carried out by a vacuum vapor deposition method using a low molecular material such as a triazole-based, oxazole-based, oxadiazole-based, silole-based or boron-based low molecular material. Also, these electron transporting materials and these electron transport materials can be formed into a film with a printing method by dissolving in a polymer such as polystyrene, polymethyl methacrylate or polyvinyl carbazole, and preparing a coating liquid for electron transport by dissolving or dispersing in a solvent such as toluene, xylene, acetone, methyl ethyl ketone, methyl isobutyl ketone, cyclohexanone, methanol, ethanol, isopropyl alcohol, ethyl acetate, butyl acetate or water alone, or as a mixed solvent.

The electron injection material for use in the electron injection layer may be, in addition to the material similar to those used in the aforementioned electron transport layer, a salt or oxide of an alkali metal or alkaline earth metal, or the like such as lithium fluoride or lithium oxide, which can be used for the film formation by vacuum evaporation. Also, these electron transporting materials and these electron transport materials can be formed into a film with a printing method by dissolving in a polymer such as polystyrene, polymethyl methacrylate or polyvinyl carbazole, and preparing a coating liquid for electron transport by dissolving or dispersing in a solvent such as toluene, xylene, acetone, methyl ethyl ketone, methyl isobutyl ketone, cyclohexanone, methanol, ethanol, isopropyl alcohol, ethyl acetate, butyl acetate or water alone, or as a mixed solvent.

When the film formation of such layers is carried out by a printing method, the coating can be performed by a printing method such as a letterpress printing method, an intaglio printing method, a screen printing method, a gravure printing method, a flexography method or an offset lithography method. However, the letterpress printing method is particularly suited for production of the organic EL device, in particular, in light of suitability to the viscosity region of the coating liquid, printability without scratching the substrate, and satisfactory efficiency of material utilization.

Following the film formation step by a wet method, a drying step is required. The drying method may be any one as long as the solvent can be eliminated to the extent that the luminescence characteristics are not deteriorated, and can be selected among methods by heating or by vacuum. Taking into consideration of thermal deterioration of the organic electroluminescence medium layer, the heat is preferably not higher than Tg of each material, and solvent elimination using a reduced state in combination is more preferred.

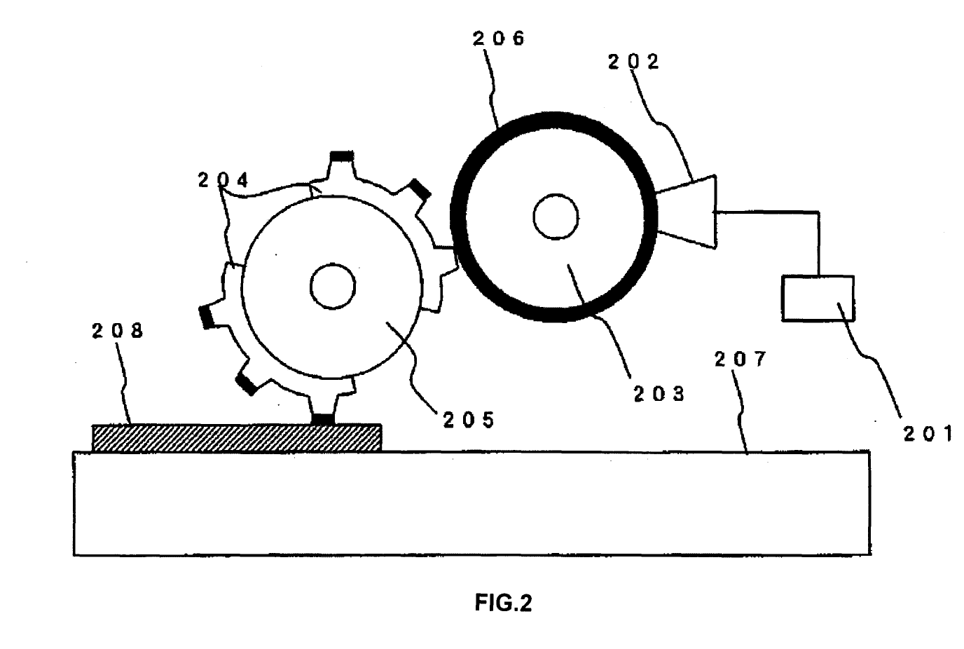

The letterpress printing method will be explained in detail with reference to FIG. 2.

FIG. 2 shows a schematic view illustrating a printing machine for carrying out letterpress printing. This printing machine has an ink tank 201, an ink chamber 202 and an anilox roll 203, and a plate cylinder 205 equipped with a resin letterpress 204. The ink tank 201 stores a coating liquid of the organic electroluminescence medium material, and to the ink chamber 202 is fed a coating liquid for printing from the ink tank 201. The anilox roll 203 is designed to rotate while being in contact with the ink feeding part of the ink chamber 202 and the plate cylinder 205.

With the rotation of the anilox roll 203, the coating liquid for printing 206 fed from the ink chamber 202 is uniformly retained on the anilox roll surface, and thereafter, is transferred to the protruding part of the resin letterpress 204 attached to the plate cylinder in a uniform film thickness. Further, the board to be printed 208 is fixed on a slidable stage 207, and is moved to a printing start position while adjusting the position by a mechanism for regulating the position of the plate pattern and the board pattern. The protruding part of the resin letterpress 204 is further moved while being in contact with the board to match the rotation of the plate cylinder. The patterning at a predetermined position of the board to be printed 208 on the stage 207 is followed by transition of the ink to complete the printing step.

As the cathode 104 that is the counter electrode, an elemental metal such as Mg, Al or Yb may be used. Also, for the purpose of achieving both electron injection efficiency and stability, an alloy system of a metal having a low work function with a stable metal, for example, an alloy such as MgAg, AlLi or CuLi, can be used. The method of forming the cathode which can be employed may be, depending on the material, a resistance heating vapor deposition method, an electron beam method, or a sputtering method. The thickness of the cathode is desirably approximately 10 nm to 1000 nm.

Finally, for the purpose of protecting the organic EL laminated body from external oxygen or moisture, encapsulation is effected using a glass cap and an adhesion whereby the organic EL device can be obtained. Also, when the translucent board has flexibility, a sealing agent and a flexible film are used to carry out the encupsulation.

According to the invention, the organic EL device which has long-lifetime and has high performance can be obtained by optimizing the hole transport layer.

Hereinafter, Examples of the organic EL device of the invention will be demonstrated, but the invention is not anyhow limited to the following Examples.

### EXAMPLE 1

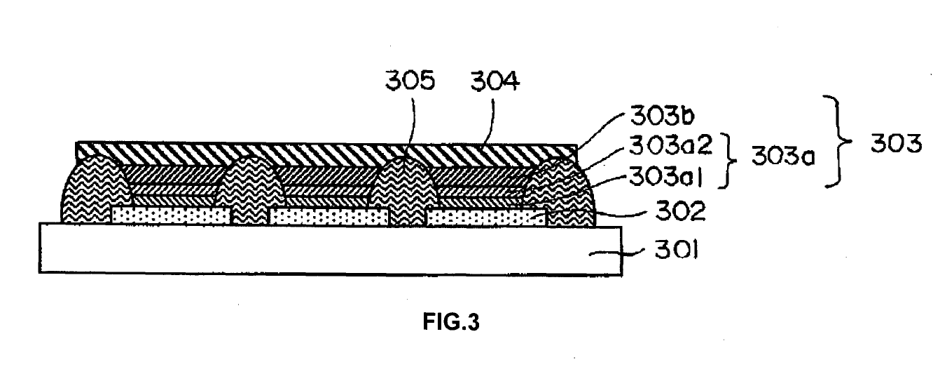

As shown in FIG. 3, using a glass board of 100 mm square having a thickness of 0.7 mm, as a translucent board 301, ITO lines with 800 μm pitch (L/S=700/100) were provided as a transparent conductive layer 302 which serves as the first electrode. Thereafter, an insulative resist was subjected to patterning by a photolithography method to provide an insulating partition 305 such that the ITO edge is covered thereby.

Subsequently, pattern formation was carried out using an ink for the hole transport layer (manufactured by Bayer AG, Baytron p CH8000) including poly(3,4-ethylenedioxythiophene)/polystyrenesulfonic acid= 1/20 (weight ratio) on the transparent conductive layer 302 by the letterpress printing method to give a thickness of 15 nm, whereby a first hole transport layer 303a1 was obtained. Further pattern formation was carried out using an ink for the hole transport layer (manufactured by Bayer AG, Baytron P AI4083) including (3,4-ethylenedioxythiophene)/polystyrenesulfonic acid=⅙ (weight ratio) on the first hole transport layer 303a1 by the letterpress printing method to give a thickness of 15 nm, whereby a second hole transport layer 303a2 was laminated. Accordingly, a hole transport layer 303a having a total thickness of 30 nm with different component ratios between the first electrode side and the organic luminescent layer side was obtained.

Subsequently, pattern formation was carried out using a 1 vol % PPV-based polymer material, 84 vol % toluene and 15 vol % anisole as the organic luminescent material on the hole transport layer 303a by the letterpress printing method, whereby an organic luminescent layer 303b was obtained. Thus, an organic electroluminescence medium layer 303 including the hole transport layer 303a and the organic luminescent layer 303b was formed. Finally, after pattern formation of MgAg as a counter electrode 304 by a binary vapor deposition method in stripes, with 800 μm pitch (L/S=700/100), so as to be perpendicular to the transparent conductive layer 302 and give a thickness of 150 nm, encupsulation was conducted using a glass cap and an adhesive to produce the organic EL device of a passive driving system.

Thus resulting passive organic EL device could light only the selected picture device alone without a short between the electrodes. In addition, half time of the luminance when the initial luminance was 500 cd/m² was 4500 hrs.

Consequently, it was revealed that a display unit having the organic EL device, which has long-lifetime and has high performance, as the display device can be provided according to the invention.

### COMPARATIVE EXAMPLE 1

In Comparative Example 1, film formation was carried out using only the ink for the hole transport layer (manufactured by Bayer AG, Baytron P CH8000) including poly(3,4-ethylenedioxythiophene)/polystyrenesulfonic acid= 1/20 as the hole transport layer 303a to give the thickness of 30 nm. Other conditions are similar to those in Example 1.

Thus resulting organic EL device of the passive driving system requires higher driving voltage as compared with the device of Example 1, and half lifetime when the initial luminance was 500 cd/m² was 2800 hrs.

### COMPARATIVE EXAMPLE 2

In Comparative Example 2, film formation was carried out using only the ink for the hole transport layer (manufactured by Bayer AG, Baytron P AI4083) including poly(3,4-ethylenedioxythiophene)/polystyrenesulfonic acid=⅙ as the hole transport layer 303a to give the thickness of 30 nm. Other conditions are similar to those in Example 1.

Thus resulting organic EL device of the passive driving system exhibited occurrence of uneven emission and shorts at several sites as compared with the device of Example 1. Half lifetime when the initial luminance was 500 cd/m² was 3000 hrs.

What is claimed is:

1. An organic electroluminescence device comprising a first electrode, an organic electroluminescence medium layer having a hole transport layer and an organic luminescent layer, and a second electrode in this order, wherein the hole transport layer includes associates of a donating molecule and an accepting molecule, and the hole transport layer has different component ratios of the donating molecule and the accepting molecule between a side of the first electrode and a side of the organic luminescent layer.

2. An organic electroluminescence device according to claim 1 wherein the hole transport layer is a laminated body of two or more layers having different component ratios of the donating molecule and the accepting molecule.

3. An organic electroluminescence device according to claim 1 wherein according to the component ratios of the donating molecule and the accepting molecule in the hole transport layer, the accepting molecules are included in a larger amount on the first electrode side, and the donating molecules are included in a larger amount on the organic luminescent layer side.

4. An organic electroluminescence device according to claim 1 wherein the hole transport layer is formed by a wet method.

5. An organic electroluminescence device according to claim 1 wherein the hole transport layer comprises poly(3,4-ethylenedioxythiophene) as the donating molecule, and polystyrenesulfonic acid as the accepting molecule.

6. An organic electroluminescence device according to claim 5 wherein the hole transport layer is a laminated body of two or more layers having different component ratios of the donating molecule and the accepting molecule; wherein weight ratio of poly(3,4-ethylenedioxythiophene)/polystyrenesulfonic acid in the layer on the first electrode side is 1/20; and wherein weight ratio of poly(3,4-ethylenedioxythiophene)/polystyrenesulfonic acid in the layer on the organic luminescent layer side is ⅙.

7. An organic electroluminescence device according to claim 5 wherein the ratio of the weight of poly(3,4-ethylenedioxythiophene)/the weight of polystyrenesulfonic acid is ⅙ to 1/20.

8. A display unit which comprises the organic electroluminescence device according to claim 1 as a display device.
